(19) United States
(12) Patent Application Publication
(10) Pub. No.: US 2025/0022800 A1
(43) Pub. Date: Jan. 16, 2025

(54) THREE-DIMENSIONAL CHIP OR WAFER STACK

(71) Applicant: International Business Machines Corporation, Armonk, NY (US)

(72) Inventors: Timothy J. Chainer, Putnam Valley, NY (US); Joshua M. Rubin, Albany, NY (US); John W. Golz, Hopewell Junction, NY (US); Mounir Meghelli, Tarrytown, NY (US); Todd Edward Takken, Brewster, NY (US); Arvind Kumar, Stamford, CT (US)

(21) Appl. No.: 18/222,193

(22) Filed: Jul. 14, 2023

(51) Int. Cl. H01L 23/528; H01L 23/00; H01L 23/48; H01L 23/522; H01L 25/10

(52) U.S. Cl. CPC H01L 23/5286; H01L 23/481; H01L 23/5226; H01L 24/16; H01L 24/81; H01L 25/105; H01L 2224/16145; H01L 2224/81

(57) ABSTRACT

A 3D chip (or wafer) stack is provided in which a customized redistribution layer is located between each semiconductor wafer of the chip (or wafer) stack. The customized redistribution layer connects functional die sites on a first semiconductor wafer to functional die sites on a second semiconductor wafer, while by-passing non-functional die sites on the second semiconductor wafer.

### BACKGROUND

The present application relates to semiconductor technology, and more particularly to a three-dimensional (3D) chip (or wafer) stack including a customized redistribution layer that is present between each stacked semiconductor wafer.

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed and greater bandwidth, as well as lower power consumption and latency has grown recently, there is a need for advanced packaging techniques of semiconductor dies to increase interconnection density and performance.

As semiconductor technologies further advance, stacked semiconductor devices, e.g., 3D integrated circuits (ICs), have emerged as an effective alternative to further reduce the physical size of a semiconductor device. In a stacked semiconductor device, active circuits such as logic, memory, processor circuits and the like can be fabricated on different semiconductor wafers. Two or more semiconductor wafers can be stacked on top of one another to reduce the form factor of the semiconductor device. Two semiconductor wafers can be bonded together through suitable bonding techniques. An electrical connection can be provided between the stacked semiconductor wafers. The stacked semiconductor devices can provide a higher density with smaller form factors and allow for increased performance and lower power consumption.

### SUMMARY

A 3D chip (or wafer) stack is provided in which a customized redistribution layer is located between each semiconductor wafer of the 3D chip (or wafer) stack. The chip (or wafer) includes one or more “die sites”, a term used throughout the present application to denote an area of the semiconductor wafer in which a set of circuits are present. A wafer map typically identifies die site location by row and column designator. The set of circuits within the die site can be fully functional and thus the die site can be referred to as a functional die site. The set of circuits within the die site can be fully non-functional and thus the die site can be referred as a non-functional die site. The set of circuits within the die site may include both functional and non-functional circuits and thus may be referred to as partially a functional die site. The customized redistribution layer connects functional circuits within die sites on a first semiconductor wafer to functional circuits within die sites on a second semiconductor wafer, while by-passing non-functional circuits within die sites on the second semiconductor wafer.

In one aspect of the present application, a 3D stack is provided. In the present application, the term ‘3D stack’ is meant to include a chip stack (after wafer stacking and dicing or after dicing and stacking) or a wafer stack (after stacking and no dicing). In one embodiment of the present application, the 3D stack includes a first semiconductor wafer including a plurality of first die sites, wherein the plurality of first die sites includes at least first functional die sites. The 3D stack further includes a second semiconductor wafer stacked above the first semiconductor wafer. The second semiconductor wafer includes a plurality of second die sites, wherein the plurality of second die sites includes second functional die sites, second partially functional die sites (in some embodiments these partially functional die sites can be optional) and second non-functional die sites. The 3D stack even further includes a redistribution layer located between the first semiconductor wafer and the second semiconductor wafer. The redistribution layer electrically connects the first functional die sites of the first semiconductor wafer to the second functional die sites, and, if present, the second partially functional die sites of the second semiconductor wafer and by-passes the second non-functional die sites of the second semiconductor wafer. In the present application, a plurality of semiconductor wafers can be stacked one on top the other, with a customized redistribution layer located between each semiconductor wafer.

In another aspect of the present application, a method of 3D stacking is provided. In one embodiment, the method includes processing a first semiconductor wafer including a plurality of first die sites and a second semiconductor wafer including a plurality of second die sites; individually testing the first die sites of the first semiconductor wafer and the second die sites of the second semiconductor wafer to determine the functionality or non-functionality of each first die site and each second die site; preparing a first semiconductor wafer map of the functionality or non-functionality of each first die site and a second semiconductor wafer map of the functionally or non-functionality of each second die site; forming, by utilizing the first semiconductor wafer map and the second semiconductor wafer map, a redistribution layer on the first semiconductor wafer to include electrically conductive wiring that electrically connects the partially and fully functional die sites of the first semiconductor wafer to the partially and fully functional die sites of the second semiconductor wafer, while by-passing non-functional die sites of the second semiconductor wafer; and attaching the first semiconductor wafer to the second semiconductor wafer. The method can be employed using a plurality of semiconductor wafers.

### BRIEF DESCRIPTION OF THE DRAWINGS

FIG. 1A is a top-down view of a first semiconductor wafer having a plurality of first die sites all of which are functional die sites.

FIG. 1B is a top-down view of a second semiconductor wafer having a plurality of second die sites including a fully non-functional die site and functional die sites.

FIG. 1C is a top-down view of a third semiconductor wafer having a plurality of third die sites all of which are functional die sites.

FIG. 1D is a top-down view of a fourth semiconductor wafer having a plurality of fourth die sites including a partially functional and fully functional die sites.

FIG. 1E is a cross-sectional view showing a redistribution layer placed on the wafer die sites of each of the first, second, third and fourth semiconductor wafers illustrated in FIGS. 1A-1B.

FIG. 2 is a top-down view showing an array of interconnects for a typical die site with signal, power, and ground.

FIG. 3A is a cross sectional view a 3D die site stack in accordance with an embodiment of the present application, the 3D die stack is assembled by stacking four semiconductor wafers stacked one atop the other with a redistribution layer located between each stacked semiconductor wafer pair and then diced. The 3D die stack may also be assembled after dicing the wafer.

FIG. 3B is a cross sectional view a 3D die site stack in accordance with an embodiment of the present application, the 3D die stack is assembled by stacking four semiconductor wafers stacked one atop the other with a redistribution layer located between each stacked semiconductor wafer pair and then diced. The 3D die stack may also be assembled after dicing the wafer.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In stacking semiconductor wafers including functional die sites and non-functional die sites, wafer assignment algorithms have been used to maximize the functional yield of the wafer-to-wafer 3D integration. Wafer assignment algorithms have limited benefit.

Another technique used in semiconductor wafers including functional die sites and non-functional die sites is to include redundant circuits in at least some of the wafers. Redundant circuits have substantial overhead and design complexity.

Neither of the above techniques enable the ability to disconnect power to a die or die circuit blocks while further enabling passthrough where needed.

The present application provides a solution to the above problems by providing a customized redistribution layer between each semiconductor wafer of a stack of semiconductor wafers. The customized redistribution layer connects fully or partial functional die sites on a first semiconductor wafer to fully or partial functional die sites on a second semiconductor wafer, while by-passing non-functional die sites on the second semiconductor wafer. The customized redistribution layer has different patterns associated with connection and by-passing.

Notably, and in one embodiment, a 3D stack, e.g., a die stack, is provided that includes a first semiconductor wafer including a plurality of first die sites, wherein the plurality of first die sites includes at least first functional die sites. The 3D stack further includes a second semiconductor wafer stacked above the first semiconductor wafer. The second semiconductor wafer includes a plurality of second die sites, wherein the plurality of second die sites includes second functional die sites and second non-functional die sites; second partially functional die sites can also be present. The 3D stack even further includes a redistribution layer located between the first semiconductor wafer and the second semiconductor wafer. The redistribution layer electrically connects the first functional die sites of the first semiconductor wafer to the second functional die sites and, if present, the second partially functional dies sites of the second semiconductor wafer and by-passes the second non-functional die sites of the second semiconductor wafer. In the present application, a plurality of semiconductor wafers can be stacked one on top the other, with a customized redistribution layer located between each semiconductor wafer. These and other aspects of the present application will now be described in greater detail.

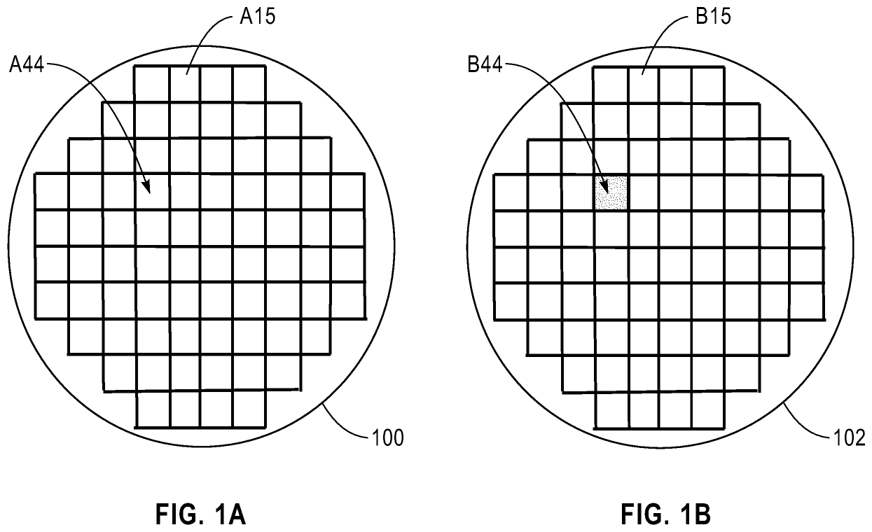

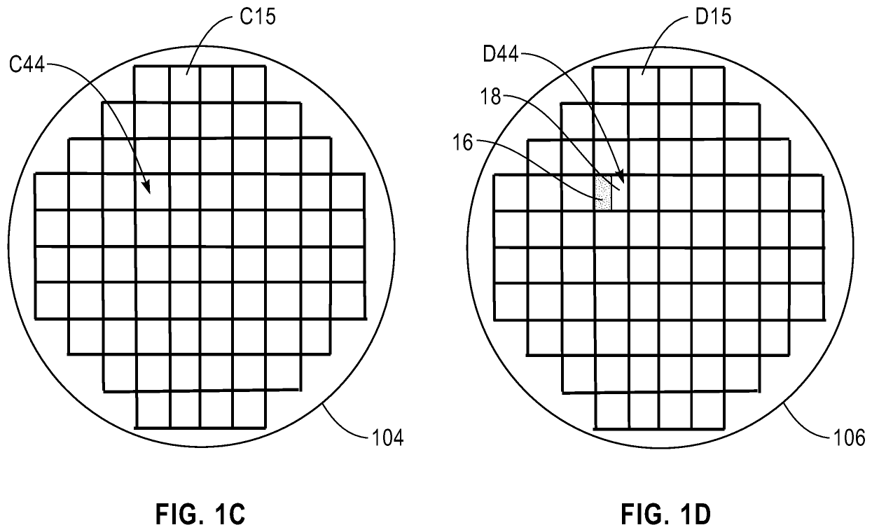

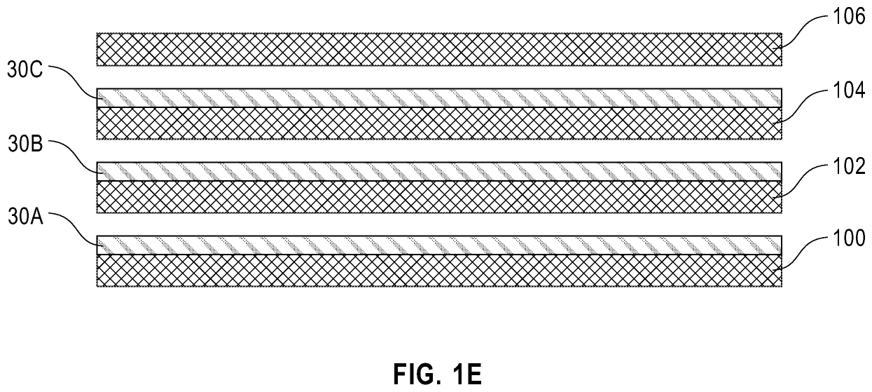

Reference is first made to FIGS. 1A, 1B, 1C and 1D, which illustrate four semiconductor wafers that can be stacked one on top the other to provide a 3D stack. Although four semiconductor wafers are described and illustrated for stacking, the present application is not limited to that number of semiconductor wafers being stacked one on top of the another. In the present application, the number of semiconductor wafers that can be stacked is n+1, wherein n is an integer starting at one. Thus, the present application contemplates embodiments in which 2 or more semiconductor wafers are to be stacked one on top the other.

The term “semiconductor wafer” is used through-out the present application to denote a substrate that is composed of at least one semiconductor material having semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments, the semiconductor wafer is a bulk semiconductor substrate that is entirely composed of one or more semiconductor materials. In other embodiments, the semiconductor wafer is a semiconductor-on-insulator substrate that includes a dielectric material such as silicon dioxide, diamond-like carbon (DLC), boron nitride or combinations thereof positioned between a first semiconductor layer and a second semiconductor layer.

Each semiconductor wafer includes a frontside and a backside. The frontside of the semiconductor wafer is a side of the semiconductor wafer that includes a front-end-of-the-line (FEOL) level, a middle-of-the-line (MOL) level and a back-end-of-the-line (BEOL) level. The FEOL level is a level in which individual components (e.g., transistors, capacitors, and/or resistors) are fabricated. On the frontside of each semiconductor wafer, the individual components can be connected by metal wires/traces (present in the MOL and BEOL levels) to form an electronic circuit (hereinafter referred to as just “circuit”). The backside of the semiconductor wafer is a side of the wafer opposite the frontside that contains the FEOL level. The backside of the semiconductor wafer contains various backside structures including, but not limited, to backside wiring structures. Through vias may be fabricated within the semiconductor wafer which provide electrical connections from the FEOL level. MOL level and BEOL level to the backside of the wafer.

In the present application, each semiconductor wafer including the four depicted in the drawings of the present application are processed to include a FEOL level, a MOL level and a BEOL level, and backside structures. Three of the semiconductor wafers exemplified in the present application include through vias which connect the frontside structures to the backside of the wafer. The topmost wafer does not have through vias. For clarity. the FEOL level, the MOL level and the BEOL level, and backside structures are not shown. The processing of the frontside and the backside includes techniques that are well known to a skilled artisan. As such, and so not to obscure any aspects of the present application the techniques used in processing the frontside and the backside are not described herein.

In the present application. cach semiconductor wafer including the four depicted in the drawings of the present application includes a plurality of die sites which in the top-down views are present in rows and columns. As mentioned above, the term “die site” is used throughout the present application to denote an area of the semiconductor wafer in which a set of circuits are present. The set of circuits within each die site can be fully functional circuits and thus the die site can be referred to as a functional die site. The set of circuits within the die site can be fully non-functional circuits and thus the die site can be referred as a non-functional die site. The set of circuit within the die site may include both functional and non-functional circuits and thus may be referred to as a partially functional die site. In the present application, a semiconductor wafer can include fully functional die sites, or a combination of fully functional die sites, partially functional die sites and fully non-functional die sites. The number of functional die sites, partially functional die sites and non-functional die sites on any given semiconductor wafer can vary and is not limited to the illustrated embodiments depicted in FIGS. 1A, 1B, 1C and 1D.

In the present application, and after processing each of the semiconductor wafers, the die sites of the wafer are tested prior to stacking to determine whether the die sites are functional die sites, partially functional die sites or non-functional die sites. Testing can include any standard die site testing process such as, for example, adaptive test, advance DFT (design for test) which can include scan and built-in self-test (BIST), fast mixed signal testers, and fine pitch probe cards. Additionally, other methods can be used to assist in determining die-site functionality, such as wafer level burn-in to eliminate infant mortality. A map of the wafer (hereinafter wafer map) can then be generated using known processes to determine which die sites are functional, partially functional and which are non-functional. The wafer map of each of the semiconductor wafers can be stored in a storage device such as, for example, on a computer hard drive, and be subsequently used in the customization of a redistribution layer. Notably, and in the present application, the wafer maps of the first and the second semiconductor wafers can be used to design a redistribution layer. In the present application, a redistribution layer is designed that connects functional die sites on the first semiconductor wafer with functional die sites (and if present, partially functional die sites) on the second semiconductor wafer, while by-passing any non-functional die site on the second semiconductor wafer. A customized redistribution layer can be designed for each of the semiconductor wafers that are to be stacked one on top of the other using the process mentioned above. In some embodiments, the customized redistribution layer can be formed on the backside of a processed semiconductor wafer, while an array of interconnects can be formed on the frontside of a processed semiconductor wafer. In some embodiments, the customized redistribution layer can be formed on the backside of a lower processed semiconductor wafer, and another customized redistribution layer can be formed on the frontside of an upper processed semiconductor wafer.

Referring now to FIGS. 1A-1D, there is illustrated four different processed semiconductor wafers which have been tested and mapped to determine the functionally of each of the die sites that are present on the semiconductor wafers. Notably, FIG. 1A illustrates a first semiconductor wafer 100 having a plurality of first die sites all of which are functional die sites. Each functional die site on the first semiconductor wafer 100 can be referred to as a first functional die, for example, die site A15 that is present at row 1, col. 5. FIG. 1A also includes die site A44 which represents one of the functional first die sites that is present at row 4, col. 4 of the grid pattern shown in FIG. 1A.

Referring now to FIG. 1B, there is illustrated a second semiconductor wafer 102 having a plurality of second die sites including a fully non-functional die site and functional die sites. Each functional die site on the second semiconductor wafer 102 can be referred to as a second functional die, for example, B15 which is present at row 1, col. 5, while each non-functional die site on the second semiconductor wafer 102 can be referred to as a second non-functional die site; note that in some embodiments the first semiconductor wafer 100 can include first non-functional die sites. In the illustrated embodiment, the second non-functional die site on the second semiconductor wafer 102 is a fully non-functional die site B44. In the illustrated embodiment, fully non-functional die site B44 is present at row 4, col. 4 of the grid pattern shown in FIG. 1B.

Referring now to FIG. 1C, there is illustrated a third semiconductor wafer 104 having a plurality of third die sites all of which are functional die sites. Each functional die site on the third semiconductor wafer 104 can be referred to as a third functional die, for example, C15 present at row 1, col. 5. Embodiments are contemplated in which the third semiconductor wafer includes non-functional die sites. FIG. 1C includes die site C44 which represents one of the functional third die sites that is present at row 4, col. 4 of the grid pattern shown in FIG. 1C.

Referring now to FIG. 1D, there is illustrated a fourth semiconductor wafer 106 having a plurality of fourth die sites including a partially functional die site and functional die sites. Each functional die site on the fourth semiconductor wafer 104 can be referred to as a fourth functional die, for example D15 which is present at row 1, col. 5, while each partially functional die site on the fourth semiconductor wafer 106 can be referred to as a fourth partially functional die site. In the illustrated embodiment, the fourth partially functional die site on the fourth semiconductor wafer 106 is a partially functional die site D44. In this embodiment, the overall die site D44 at row 4, col. 4 includes a functional die site circuit block 18 that is present on the right side of at row 4, col. 4 of the grid pattern and a non-functional die site circuit block 16 that is present at the left side of row 4, col. 4 as shown in FIG. 1D.

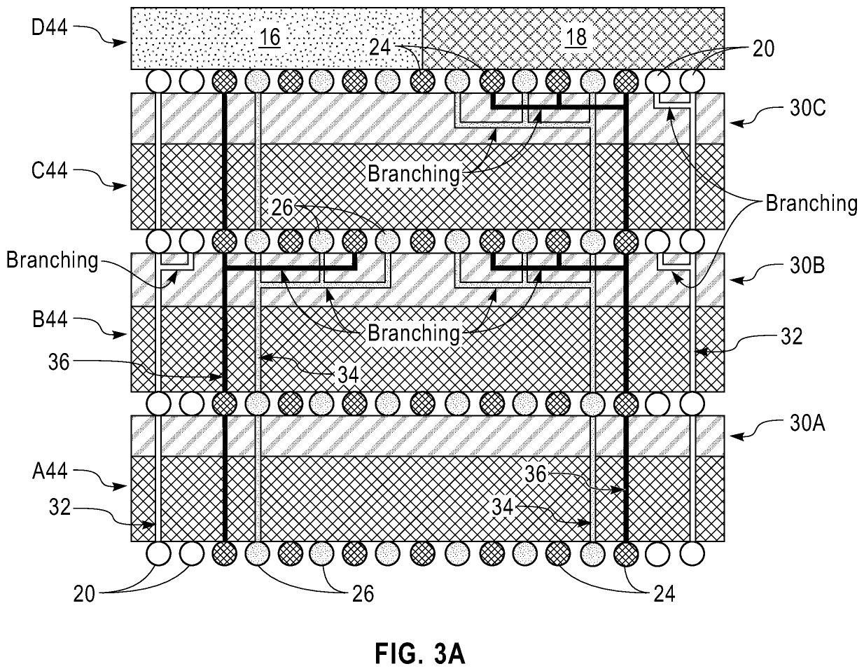

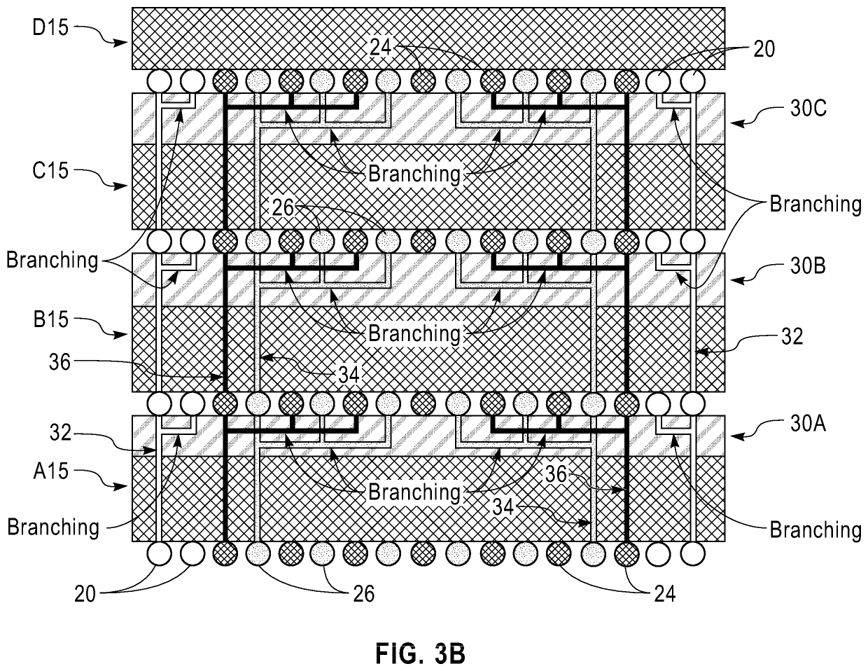

In the illustrated example shown in FIGS. 3A and 3B a first redistribution layer can be designed that connects the first functional die sites A15 on the first semiconductor wafer 100 with second functional die site B15 on the second semiconductor wafer 102, while by-passing the fully non-functional die site B44 on the second semiconductor wafer 102. A second redistribution layer can be designed that connects the second functional die sites B15 and by-passed non-functional die site B44 on the second semiconductor wafer 102 with the third functional die sites C15 and C44, respectively, on the third semiconductor wafer 104. A third redistribution layer can be designed that connects the third functional die sites C15 and C44 on the third semiconductor wafer 104 with the fourth functional die site D15 and partially function die site D44, respectively on the fourth semiconductor wafer 104, while by-passing the non-functional die site circuit block 18 of the partially functional die site D44 on the fourth semiconductor wafer 104.

In the present application, the term “redistribution layer” denotes an interconnect structure that contains electrically conductive wires embedded in an interconnect dielectric layer. The electrically conductive wires can be composed of an electrically conductive metal or an electrically conductive metal alloy. Exemplary electrically conductive materials (i.e., metal or metal alloys) that can provide electrically conductive wires of the redistribution layer include, but are not limited, copper (Cu), aluminum (Al), tungsten (W), cobalt (Co), ruthenium (Ru), rhodium (Rh), platinum (Pt) and alloys of Cu—Al. The interconnect dielectric layer includes one or more interconnect dielectric materials. Illustrative interconnect dielectric materials that can be used as the interconnect dielectric layer of the redistribution layer include, but are not limited to, silicon dioxide, undoped or doped silicate glass, silsesquioxanes, C doped oxides (i.e., organosilicates) that include atoms of Si, C, O and H, theremosetting polyarylene ethers, polyimides, polybenzoxazole (PBO) or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

In embodiments, a diffusion barrier liner can be present on at least the sidewalls of each of the electrically conductive wires present in the redistribution layer. In some embodiments, no diffusion barrier liner is employed. When present, the diffusion barrier liner is composed of a diffusion barrier material such as, for example, Ta. TaN, Ti, TiN, Ru, RuN, RuTa, RuTaN, W. WN or any other material that can serve as a barrier to prevent a conductive material from diffusing there through.

The redistribution layer can be formed utilizing processes well known to one skilled in the art. The redistribution layer can be formed by additive processes, such a copper plating through a photoresist mask and subsequent planarization within a dielectric, or a subtractive process, as described herein, a semi-additive process or any combination thereof. In one example, the redistribution layer can be formed utilizing a damascene process. In a damascene process, the interconnect dielectric layer is formed by a deposition process such as, for example, chemical vapor deposition (CVD), plasma enhanced chemical vapor deposition (PECVD), or spin-on coating. Openings are then formed into the as deposited interconnect dielectric layer by lithography and etching. If present, a layer of a diffusion barrier material can then be formed followed by a layer of an electrically conductive material. A planarization process is then performed to remove the optional layer of diffusion barrier material and the layer of electrically conductive material from outside the openings forming the optional diffusion barrier liner and the electrically conductive wire in each of the openings. The electrically conductive wiring of the redistribution layer can be connected to signal interconnects (i.e., lines) power interconnects (i.e., lines), and ground interconnects (i.c., lines) that can be present in a typical die site on a semiconductor wafer, including the various die sites on the semiconductor wafers shown in FIGS. 1A-1D. The redistribution layer is fabricated to include electrically conductive wiring that connects functional die sites on a lower semiconductor wafer of a stacked pair of semiconductor wafers to functional die sites on an upper semiconductor wafer of the stacked wafer pair, while by-passing any non-functional die site or die site circuit block on the upper semiconductor wafer. A reticle can be designed using the wafer maps and that reticle can be used to form the redistribution layer. Alternate approaches to patterning can be considered. Some examples include laser patterning of features to enable customization of one or more redistribution layers. Additionally, subtractive laser ablation or ion-beam milling of features can be used to modify an existing redistribution layer structure to change connectivity between die sites.

Referring now to FIG. 1E, there is illustrated a redistribution layer placed on the die sites of each of the first semiconductor wafer 100, second semiconductor wafer 102, third semiconductor wafer 104 and fourth semiconductor wafer 106. Notably, a first redistribution layer 30A is placed on the first semiconductor wafer 100, a second redistribution layer 30B is placed on the second semiconductor wafer 102, and a third redistribution layer 30C is placed on the third semiconductor wafer 104. Each redistribution layer has been customized for each individual die site as defined above.

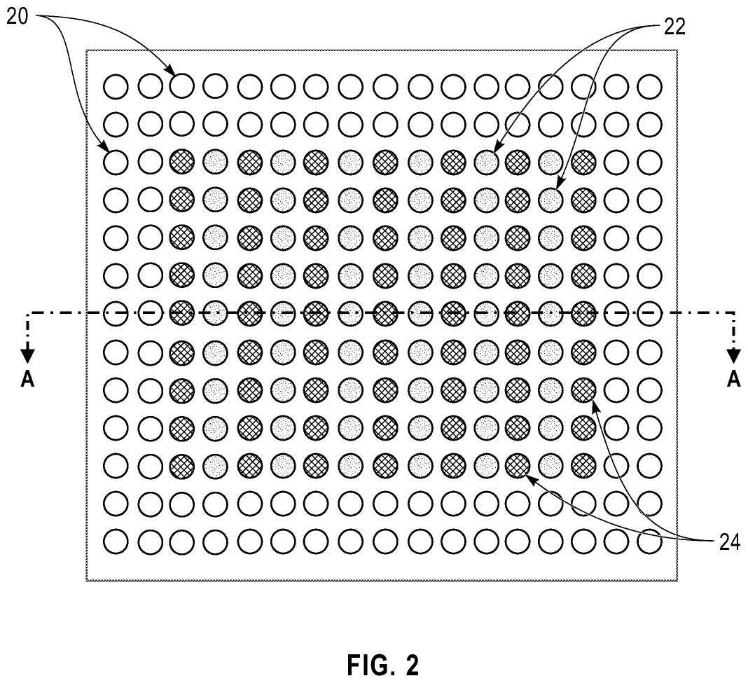

Referring now to FIG. 2, there is illustrated an array of interconnects for a typical die site with signal, power, and ground. Notably, FIG. 2 illustrates an array of signal interconnects 20, power interconnects 22, and ground interconnects 24. The signal interconnects 20, power interconnects 22, and ground interconnects 24 are formed. The signal interconnects 20, power interconnects 22, and ground interconnects 24 can be formed utilizing techniques that are well known to those skilled in the art. The signal interconnects 20, power interconnects 22, and ground interconnects 24 can be solder balls, metal pad structures or a combination thereof. The signal interconnects 20 can be connected to signal lines that can be present in each of the semiconductor wafers, the power interconnects 22 can be connected to power lines that can be present in each of the semiconductor wafers, and the ground interconnects 24 can be connected to power lines that can be present in each of the semiconductor wafers. FIG. 2 includes a cut A-A which pass through a row on interconnects within the array of interconnects and this cut will be used in FIGS. 3A and 3B.

In embodiments of the present application, the redistribution layer is in direct contact with a backside of a lower semiconductor wafer of a stacked wafer pair and is electrically connected to a frontside of an upper semiconductor wafer of the stacked wafer pair via one or more interconnects, i.e., the signal interconnects 20, power interconnects 22, and ground interconnects 24 mentioned above.

Referring now to FIGS. 3A and 3B, there is illustrated a single die site of the 3D stack in accordance with an embodiment of the present application. The 3D stack includes the four semiconductor wafers (illustrated in FIGS. 1A-1D) stacked one atop the other with a redistribution layer located between each stacked semiconductor wafer pair; FIG. 3A is a cross sectional view through A-A shown in FIG. 2.

Notably, FIG. 3A illustrates a first redistribution layer 30A which is located between the first semiconductor wafer 100 and the second semiconductor wafer 102, a second redistribution layer 30B which is located between the second semiconductor after 102 and the third semiconductor wafer 104, and a third redistribution layer 30C which is located between the third semiconductor wafer 104 and the fourth semiconductor wafer 106; note the FIG. 3A does not shows the individual semiconductor wafers, but shows specific die sites, namely die sites A44, B44, C44 and D44 mentioned above, within each of the semiconductor wafers. The array of signal interconnects 20, power interconnects 22, and ground interconnects 24 shown in FIG. 2 are present on the frontside of each of the four semiconductor wafers illustrated in FIG. 3A. Also shown in FIG. 3A are signal lines 32, power lines 34 and ground lines 36 which can be present in each die site on the semiconductor wafers. In embodiments, the signal lines 32 are connected to active circuits present in each fully or partially functional die site. In embodiments, the power line 34 and ground line 36 are connected to active circuits in each fully or partially functional die site.

The signal lines 32, power lines 34 and ground lines 36 are composed of one of the electrically conductive materials mentioned above for the electrically conductive wiring that is present in each of the first, second and third redistribution layers 30A, 30B and 30C; in the present application, a portion of each of the signal lines 32, power lines 34 and ground lines 36 within the first, second and third redistribution layers 30A, 30B and 30C represents that electrically conductive wiring, while a remaining portion of the signal lines 32, power lines 34 and ground lines 36 present in each of the first, second, and third semiconductor wafers 100, 102 and 104 represents through via wiring that is present in each of the wafers; the wiring is fabricated within each wafer prior to wafer stacking. The through via wiring electrically connects the backside of the semiconductor wafer to the frontside of the semiconductor wafer.

Also, shown in FIG. 3A are dies sites located at row 4, col. 4 of each of the first, second, third and fourth semiconductor wafers 100, 102, 104 and 106. Notably, the first semiconductor wafer 100 includes fully functional die site A44. The second semiconductor wafer 102 includes fully non-functional die site B44. The third semiconductor wafer 104 includes fully functional die site C44. The fourth semiconductor wafer 106 includes partially functional die site D44.

In the illustrated embodiment shown in FIG. 3A, the first redistribution layer 30A does not connect the signal lines 32 and the power lines 34 and ground lines 36 of die site A44 to the fully non-functional die site B44 of the second semiconductor wafer 102. This evidenced by the lack of any branching within the wiring within the first redistribution layer 30A.

In the illustrated embodiment shown in FIG. 3A, the second redistribution layer 30B does connect the signal lines 32 and the power lines 34 and ground lines 36 of die site B44 to a third functional die site C44 of the third semiconductor wafer 104. This evidenced by the branching within the wiring within the second redistribution layer 30B.

In the illustrated embodiment shown in FIG. 3A, the third redistribution layer 30C does connect the signal lines 32, power lines 34 and ground lines 36 of die site C44 to the die site D44 functional circuit block 18 and does not connect the signal lines 32, power lines 34 and ground 36 to the die site D44 of the non-functional circuit block 16 which are present on the fourth semiconductor wafer 106. The connection is evidenced by the branching within the wiring of the third redistribution layer 30C on the right most functional circuit block 18, and no branching on the non-functional circuit block 16.

FIG. 3B illustrates a first redistribution layer 30A which is located between the first semiconductor wafer 100 and the second semiconductor wafer 102, a second redistribution layer 30B which is located between the second semiconductor after 102 and the third semiconductor wafer 104, and a third redistribution layer 30C which is located between the third semiconductor wafer 104 and the fourth semiconductor wafer 106; note the FIG. 3B does not shows the semiconductor wafers, but shows specific functional die sites on the semiconductor wafers, namely die sites A15, B15, C15 and D15 corresponding to row 1, col. 5 within each of the semiconductor wafers. The array of signal interconnects 20, power interconnects 22, and ground interconnects 24 shown in FIG. 2 are present on the frontside of each of the four semiconductor wafers illustrated in FIG. 3B. Also shown in FIG. 3B are signal lines 32, power lines 34 and ground lines 36 which can be present in each die site on the semiconductor wafers. In embodiments, the signal lines 32 are connected to active circuits present in each fully or partially functional die site. In embodiments, the power line 34 and ground line 36 are connected to active circuits in each fully or partially functional die site.

In the illustrated embodiment shown in FIG. 3B, the first redistribution layer 30A connects the signal lines 32, the power lines 34 and ground lines 36 of die site A15 to the fully functional die site B15 of the second semiconductor wafer 102. This evidenced by the branching within the wiring within the first redistribution layer.

In the illustrated embodiment shown in FIG. 3B, the first redistribution layer 30B connects the signal lines 32, the power lines 34 and ground lines 36 of die site B15 to the fully functional die site C15 of the third semiconductor wafer 104. This evidenced by the branching within the wiring within the first redistribution layer.

In the illustrated embodiment shown in FIG. 3B, the first redistribution layer 30C connects the signal lines 32, the power lines 34 and ground lines 36 of die site C15 to the fully functional die site D15 of the fourth semiconductor wafer 106. This evidenced by the branching within the wiring within the first redistribution layer.

The 3D stacking can be performed by first forming in any order, an array of interconnects, as defined above, on the frontside of each semiconductor wafer that is to be stacked and a redistribution layer (as defined above) on the backside of a lower semiconductor wafer of a semiconductor wafer bonding pair. In some embodiments another customized redistribution layer can be formed on the frontside of a semiconductor wafer to be stacked. The array of interconnects of a top semiconductor wafer of the semiconductor wafer bonding pair is then brought in intimate contact with the redistribution layer that is formed on the bottom semiconductor wafer of the semiconductor wafer bonding pair. Heat can then be applied to ensure bonding of the two semiconductor wafers. Embodiments include other means of attaching the wafer together. Dicing can occur after chip stacking as is known to those skilled in the art.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A three-dimensional (3D) stack comprising:
a first semiconductor wafer comprising a plurality of first die sites, wherein the plurality of first die sites comprises at least first functional die sites;
a second semiconductor wafer stacked above the first semiconductor wafer and comprising a plurality of second die sites, wherein plurality of second die sites comprises second functional die sites and second non-functional die sites; and
a first redistribution layer located between the first semiconductor wafer and the second semiconductor wafer, wherein the first redistribution layer electrically connects the first functional die sites of the first semiconductor wafer to the second functional die sites of the second semiconductor wafer and by-passes the second non-functional die sites of the second semiconductor wafer.

2. The 3D stack of claim 1, further comprising at least one second partially functional die site on the second semiconductor wafer, wherein the first redistribution layer further connects the fully functional die sites of the first semiconductor wafer to the at least one partially functional die sites on the second semiconductor wafer.

3. The 3D stack of claim 1, the first redistribution layer is in direct contact with a backside of the first semiconductor wafer and is electrically connected to a frontside of the second semiconductor wafer via a plurality of interconnects.

4. The 3D stack of claim 3, wherein the plurality of interconnects comprises an array of signal interconnects, power interconnects and ground interconnects.

5. The 3D stack of claim 3, wherein the plurality of interconnects comprises solder balls, metal bond pads or a combination thereof.

6. The 3D stack of claim 1, wherein a frontside of the first semiconductor wafer is electrically connected to the first redistribution layer located on a backside of the second semiconductor wafer.

7. The 3D stack of claim 1, further comprising at least one signal line, at least one power line and at least one ground line present in each of the first semiconductor wafer and the second semiconductor wafer.

8. The 3D stack of claim 7, wherein the at least one signal line is electrically isolated from an active circuit present in one of the first functional die sites and one of the second functional die sites.

9. The 3D stack of claim 7, wherein the at least one power line is not connected to an active circuit present in in one of the first functional die sites and one of the second functional die sites.

10. The 3D stack of claim 1, wherein the first redistribution layer is customized to include electrically conductive wires that electrically connect the first functional die sites of the first semiconductor wafer to the second functional die sites of the second semiconductor wafer and that bypasses the second non-functional die sites of the second semiconductor wafer.

11. The 3D stack of claim 10, wherein the electrically conductive wires present in the first redistribution layer connect at least one signal line, at least one power line and at least one ground line that is present in the first semiconductor wafer and to interconnects that are present on a frontside of the second semiconductor wafer.

12. The 3D stack of claim 1, wherein the first functional die sites and the second functional die sites comprise active circuits.

13. The 3D stack of claim 1, wherein the second non-functional dies comprise at least a partially inactive active circuit.

14. The 3D stack of claim 1, wherein the 3D stack is a chip stack.

15. The 3D stack of claim 1, wherein the 3D stack is a wafer stack.

16. The 3D stack of claim 1, wherein the first redistribution layer comprises an interconnect structure that contains electrically conductive wires embedded in an interconnect dielectric layer.

17. The 3D stack of claim 1, wherein the first redistribution layer has different patterns for electrically connecting the first functional die sites of the first semiconductor wafer to the second functional die sites of the second semiconductor wafer and for by-passing the second non-functional die sites of the second semiconductor wafer.

18. The 3D stack of claim 1, further comprising:
a third semiconductor wafer stacked above the second semiconductor wafer and comprising a plurality of third die sites, wherein plurality of third die sites comprises third functional die sites; and
a second redistribution layer located between the second semiconductor wafer and the third semiconductor wafer, wherein the second redistribution layer electrically connects the second functional die sites of the second semiconductor wafer to the third functional die sites of the third semiconductor wafer.

19. The 3D stack of claim 18, further comprising:
a fourth semiconductor wafer stacked above the third semiconductor wafer and comprising a plurality of fourth die sites, wherein plurality of fourth die sites comprises fourth functional die sites and a non-functional die site; and
a third redistribution layer located between the third semiconductor wafer and the fourth semiconductor wafer, wherein the third redistribution layer electrically connects the third functional die sites of the third semiconductor wafer to the fourth functional die sites of the fourth semiconductor wafer and by-passes the non-functional die site on the fourth semiconductor wafer.

20. A method of 3D stacking, the method comprising:
processing a first semiconductor wafer comprising a plurality of first die sites and a second semiconductor wafer comprising a plurality of second die sites;
individually testing first die sites of the first semiconductor wafer and the second die sites determine the functionality or non-functionality of each first die site of the plurality of first die sites and each second die site of the plurality of second die sites;
preparing a first semiconductor map of the functionality or non-functionality of each first die site or the plurality of first die sites and a second semiconductor map of the functionally or non-functionality of each second die site of the plurality of second die sites;
forming, by utilizing the first semiconductor map and the second semiconductor map, a redistribution layer on the first semiconductor wafer to include electrically conductive wiring that electrically connects the functional die sites of the first semiconductor wafer to the functional die sites of the second semiconductor wafer, while by-passing non-functional die sites of the second semiconductor wafer; and
attaching the first semiconductor wafer to the second semiconductor wafer.
